(19) United States
(12) Patent Application Publication
(10) Pub. No.: US 2022/0238728 A1
(43) Pub. Date: Jul. 28, 2022

(54) DIODE, METHOD FOR PRODUCING DIODE, AND ELECTRONIC DEVICE

(71) Applicant: POWDEC K.K., Tochigi (JP)

(72) Inventors: Hiroji KAWAI, Tochigi (JP); Shuichi YAGI, Tochigi (JP); Takeru SAITO, Tochigi (JP); Fumihiko NAKAMURA, Tochigi (JP); Hironobu NARUI, Tochigi (JP)

(21) Appl. No.: 17/615,462

(22) PCT Filed: Mar. 5, 2020
(86) PCT No.: PCT/JP2020/009283

§ 371 Date: Nov. 30, 2021

(30) Foreign Application Priority Data
Nov. 29, 2019 (JP) 2019-215950

(51) Int. Cl. H01L 29/872; H01L 29/06; H01L 29/20; H01L 29/205; H01L 29/66

(52) U.S. Cl. CPC H01L 29/872; H01L 29/0634; H01L 29/66143; H01L 29/205; H01L 29/2003

(57) ABSTRACT

This diode is configured by a double gate PSJ-GaN-based FET. This FET has a GaN layer 11, an AlₓGa₁₋ₓN layer 12, an undoped GaN layer 13, and a p-type GaN layer 14. A source electrode 19 and a drain electrode 20 are provided on the AlₓGa₁₋ₓN layer 12, a first gate electrode 15 is provided on the p-type GaN layer 14, and a second gate electrode 18 is provided on a gate insulating film 17 provided inside a groove 16 which is provided in the AlₓGa₁₋ₓN layer 12 between the source electrode 19 and the undoped GaN layer 13. The source electrode 19, the first gate electrode 15, and the second gate electrode 18 are connected to each other. Or the source electrode 19 and the second gate electrode 18 are connected to each other, and a positive voltage is applied to the first gate electrode 15 for the source electrode 19 and the second gate el electrode 18.

### TECHNICAL FIELD

The present invention relates to a diode, a method for producing diode, and an electric equipment and, more particularly to a diode configured by a double gate polarization superjunction (PSJ) field effect transistor using gallium nitride (GaN)-based semiconductor and a method for producing the diode and an electric equipment using the diode.

### BACKGROUND ART

Conventionally, the PSJ-GaN-based diode has been known as a high voltage resistance power diode (see patent literatures 1 and 2). The PSJ-GaN-based diode is configured by a three-terminal PSJ-GaN-based field effect transistor (FET). The PSJ-GaN-based FET has, typically, a PSJ region comprising an undoped GaN layer, an AlₓGa₁₋ₓN layer and an undoped GaN layer which are stacked in order and a contact region provided adjacent to the PSJ region, comprising an undoped GaN layer, an AlₓGa₁₋ₓN layer, an undoped GaN layer and a p-type GaN layer which are stacked in order. And a gate electrode is provided on the p-type GaN layer of the contact region, a source electrode and a drain electrode are provided on the AlₓGa₁₋ₓN layer on both sides of the PSJ region and the contact region such that the source electrode and the drain electrode sandwich them, and the source electrode and the gate electrode are connected to each other. In the PSJ-GaN-based diode configured by the PSJ-GaN-based FET, the source electrode and the gate electrode serve as an anode electrode, and the drain electrode serves as a cathode electrode.

### PRIOR ART LITERATURE

### Patent Literature

PATENT LITERATURE 1 Specification of U.S. Pat. No. 5,828,435 (see particularly paragraph 0069 and FIG. 23)
PATENT LITERATURE 2 Specification of U.S. Pat. No. 5,669,119 (see particularly paragraph 0117 and FIG. 34)

### SUMMARY OF INVENTION

### Subjects to be Solved by Invention

However, with respect to the conventional PSJ-GaN-based diode, there is still room for improvement in energy loss. That is, although the diode can switch large electric power at high speed, its on voltage is equal to or higher than that of conventional general GaN-based Schottky diodes.

Therefore, the subject to be solved by the invention is to provide a diode which can be used as a high voltage resistance power diode capable of switching large electric power at high speed and which can lower on voltage as compared conventional GaN-based Schottky diodes and reduce energy loss, and a method for producing the diode.

Another subject to be solved by the invention is to provide a high performance electric equipment using the above diode.

### Means to Solve the Subjects

In order to solve the object, according to the invention, there is provided a diode configured by a double gate polarization superjunction GaN-based field effect transistor, comprising:

a first GaN layer,

an AlₓGa₁₋ₓN layer (0<x<1) on the first GaN layer,

an undoped second GaN layer having a first island-like shape on the AlₓGa₁₋ₓN layer,

a p-type GaN layer having a second island-like shape on the second GaN layer,

a source electrode and a drain electrode provided on the AlₓGa₁₋ₓN layer such that the source electrode and the drain electrode sandwich the second GaN layer,

a first gate electrode which is electrically connected to the p-type GaN layer; and

a second gate electrode provided on a gate insulating film provided inside a groove which is provided in the AlₓGa₁₋ₓN layer between the source electrode and the second GaN layer,

the threshold voltage of the second gate electrode being not lower than 0 V,

the source electrode, the first gate electrode and the second gate electrode being electrically connected to each other, or the source electrode and the second gate electrode being electrically connected to each other and a positive voltage being applied to the first gate electrode for the source electrode and the second gate electrode,

an anode electrode being configured by the source electrode, the first gate electrode and the second gate electrode or the source electrode and the second gate electrode and a cathode electrode being configured by the drain electrode.

In the diode, thicknesses, types of conductivity, compositions and so on of the first GaN layer, the AlₓGa₁₋ₓN layer and the second GaN layer configuring the polarization superjunction region are determined based on disclosure of patent literatures 1 and 2, for example. For example, although the first GaN layer and the AlₓGa₁₋ₓN layer are typically undoped, they may be lightly doped with p-type impurity or n-type impurity as necessary. The Al composition x of the AlₓGa₁₋ₓN layer is also determined based on disclosure of patent literatures 1 and 2, for example. The first gate electrode electrically connected to the p-type GaN layer is typically provided on the p-type GaN layer. In this case, the concentration of p-type impurity of the surface of the p-type GaN layer is preferably set to be higher concentration to reduce contact resistance.

In the diode, at a non-operating time, a two-dimensional hole gas (2DHG) is formed in the second GaN layer in the vicinity part of a hetero-interface between the AlₓGa₁₋ₓN layer and the second GaN layer, and a two-dimensional electron gas (2DEG) is formed in the first GaN layer in the vicinity part of a hetero-interface between the first GaN layer and the AlₓGa₁₋ₓN layer. In the diode, control by the first gate electrode is normally-on type, and control by the second gate electrode is normally-off type. Since control by the first gate electrode is normally-on type and control by the second gate electrode is normally-off type, when a voltage not lower than the threshold voltage Vₜₕ is not applied to the second gate electrode, the diode is off due to absence of the 2DEG directly below the second gate electrode, whereas when a voltage not smaller than the threshold voltage Vₜₕ is applied to the second gate electrode, the 2DEG channel is formed such that it connects the source electrode and the drain electrode and the diode is turned on.

In order to electrically connect the source electrode, the first gate electrode and the second gate electrode to each other, typically, an electrode is provided such that the electrode covers the source electrode, the first gate electrode and the second gate electrode. In order to electrically connect the source electrode and the second gate electrode to each other, typically, an electrode is provided such that the electrode covers the source electrode and the second gate electrode.

The thickness of the part of the AlₓGa₁₋ₓN layer at the groove provided in the AlₓGa₁₋ₓN layer between the source electrode and the second GaN layer is generally not smaller than 3 nm and not larger than 100 nm and is typically not smaller than 3 nm and not larger than 30 nm.

The gate insulating film is made of p-type semiconductor or insulator. The p-type semiconductor is, for example, p-type GaN, p-type InGaN, NiOₓ and so on, but not limited to these. The p-type semiconductor is regarded insulator because it is thin film and depleted. The p-type semiconductor is p like and effective to increase the electron barrier of the channel and reduce leakage current. The insulator may be, for example, inorganic oxides, inorganic nitrides, inorganic oxynitrides and so on. More specifically, the insulator may be, for example, Al₂O₃, SiO₂, AlN, SiNₓ, SiON and so on, but not limited to these.

The diode can be produced by various methods. The diode is preferably produced by following methods.

That is, according to the invention, there is provided a method for producing a diode configured by a double gate polarization superjunction GaN-based field effect transistor, comprising:

a first GaN layer,

an AlₓGa₁₋ₓN layer (0<x<1) on the first GaN layer,

an undoped second GaN layer having a first island-like shape on the AlₓGa₁₋ₓN layer,

a p-type GaN layer having a second island-like shape on the second GaN layer,

a source electrode and a drain electrode provided on the AlₓGa₁₋ₓN layer such that the source electrode and the drain electrode sandwich the second GaN layer,

a first gate electrode which is electrically connected to the p-type GaN layer; and

a second gate electrode provided on a gate insulating film provided inside a groove which is provided in the AlₓGa₁₋ₓN layer between the source electrode and the second GaN layer,

the threshold voltage of the second gate electrode being not lower than 0 V,

the source electrode, the first gate electrode and the second gate electrode being electrically connected to each other, or the source electrode and the second gate electrode being electrically connected to each other and a positive voltage being applied to the first gate electrode for the source electrode and the second gate electrode,

an anode electrode being configured by the source electrode, the first gate electrode and the second gate electrode or the source electrode and the second gate electrode and a cathode electrode being configured by the drain electrode, comprising steps of:

growing the first GaN layer, the AlₓGa₁₋ₓN layer, the second GaN layer and the p-type GaN layer on the whole surface of a base substrate in order,

forming the groove by etching a part of the p-type GaN layer, the second GaN layer and the AlₓGa₁₋ₓN layer corresponding to an area for forming the groove to the depth in the middle of the AlₓGa₁₋ₓN layer,

growing a p-type GaN layer for forming the gate insulating film on the p-type GaN layer such that the p-type GaN layer for forming the gate insulating film fills the groove,

forming the second island-like shape and the gate insulating film by patterning the p-type GaN layer for forming the gate insulating film and the p-type GaN layer by etching,

forming the source electrode and the drain electrode on the AlₓGa₁₋ₓN layer,

forming the first gate electrode and the second gate electrode on the p-type GaN layer for forming the gate insulating film formed as the second island-like shape and the gate insulating film, respectively; and

forming an electrode which covers the source electrode, the first gate electrode and the second gate electrode or an electrode which covers the source electrode and the second gate electrode.

Furthermore, according to the invention, there is provided a method for producing a diode configured by a double gate polarization superjunction GaN-based field effect transistor, comprising:

a first GaN layer,

an AlₓGa₁₋ₓN layer (0<x<1) on the first GaN layer,

an undoped second GaN layer having a first island-like shape on the AlₓGa₁₋ₓN layer,

a p-type GaN layer having a second island-like shape on the second GaN layer,

a source electrode and a drain electrode provided on the AlₓGa₁₋ₓN layer such that the source electrode and the drain electrode sandwich the second GaN layer,

a first gate electrode which is electrically connected to the p-type GaN layer; and

a second gate electrode provided on a gate insulating film provided inside a groove which is provided in the AlₓGa₁₋ₓN layer between the source electrode and the second GaN layer,

the threshold voltage of the second gate electrode being not lower than 0 V,

the source electrode, the first gate electrode and the second gate electrode being electrically connected to each other, or the source electrode and the second gate electrode being electrically connected to each other and a positive voltage being applied to the first gate electrode for the source electrode and the second gate electrode,

an anode electrode being configured by the source electrode, the first gate electrode and the second gate electrode or the source electrode and the second gate electrode and a cathode electrode being configured by the drain electrode, comprising steps of:

growing the first GaN layer, the AlₓGa₁₋ₓN layer, the second GaN layer and the p-type GaN layer on the whole surface of a base substrate in order,

patterning the p-type GaN layer and the second GaN layer by etching as the second island-like shape and the first island-like shape, respectively,

forming the source electrode and the drain electrode on the AlₓGa₁₋ₓN layer,

forming the groove by etching a part of the AlₓGa₁₋ₓN layer corresponding to an area for forming the groove to the depth in the middle of the AlₓGa₁₋ₓN layer,

forming the gate insulating film inside the groove,

forming the first gate electrode and the second gate electrode on the p-type GaN layer and the gate insulating film, respectively; and

forming an electrode which covers the source electrode, the first gate electrode and the second gate electrode or an electrode which covers the source electrode and the second gate electrode.

Furthermore, according to the invention, there is provided a method for producing a diode configured by a double gate polarization superjunction GaN-based field effect transistor, comprising:

a first GaN layer,

an AlₓGa₁₋ₓN layer (0<x<1) on the first GaN layer,

an undoped second GaN layer having a first island-like shape on the AlₓGa₁₋ₓN layer,

a p-type GaN layer having a second island-like shape on the second GaN layer,

a source electrode and a drain electrode provided on the AlₓGa₁₋ₓN layer such that the source electrode and the drain electrode sandwich the second GaN layer,

a first gate electrode which is electrically connected to the p-type GaN layer; and

a second gate electrode provided on a gate insulating film provided inside a groove which is provided in the AlₓGa₁₋ₓN layer between the source electrode and the second GaN layer,

the threshold voltage of the second gate electrode being not lower than 0 V,

the source electrode, the first gate electrode and the second gate electrode being electrically connected to each other, or the source electrode and the second gate electrode being electrically connected to each other and a positive voltage being applied to the first gate electrode for the source electrode and the second gate electrode,

an anode electrode being configured by the source electrode, the first gate electrode and the second gate electrode or the source electrode and the second gate electrode and a cathode electrode being configured by the drain electrode, comprising steps of:

growing the first GaN layer, a first AlₓGa₁₋ₓN layer and a p-type GaN layer for forming the gate insulating film on the whole surface of a base substrate in order,

forming a first mask made of inorganic insulator having the same shape as the groove on the p-type GaN layer for forming the gate insulating film,

forming the gate insulating film by patterning the p-type GaN layer for forming the gate insulating film by etching using the first mask as an etching mask,

growing a second AlₓGa₁₋ₓN layer, the second GaN layer and the p-type GaN layer on the first AlₓGa₁₋ₓN layer using the first mask as a growth mask in order,

forming a second mask made of inorganic insulator having the same shape as the second island-like shape on the p-type GaN layer,

patterning the p-type GaN layer by etching using the second mask as an etching mask,

forming a third mask made of inorganic insulator having the same shape as the first island-like shape such that the third mask covers the second mask,

patterning the second GaN layer by etching using the third mask as an etching mask,

forming the source electrode and the drain electrode on the second AlₓGa₁₋ₓN layer,

forming the first gate electrode and the second gate electrode on the p-type GaN layer and the gate insulating film, respectively; and

forming an electrode which covers the source electrode, the first gate electrode and the second gate electrode or an electrode which covers the source electrode and the second gate electrode.

Furthermore, according to the invention, there is provided an electric equipment comprising at least one diode,

the diode being configured by a double gate polarization superjunction GaN-based field effect transistor, comprising:

a first GaN layer,

an AlₓGa₁₋ₓN layer (0<x<1) on the first GaN layer,

an undoped second GaN layer having a first island-like shape on the AlₓGa₁₋ₓN layer,

a p-type GaN layer having a second island-like shape on the second GaN layer,

a source electrode and a drain electrode provided on the AlₓGa₁₋ₓN layer such that the source electrode and the drain electrode sandwich the second GaN layer,

a first gate electrode which is electrically connected to the p-type GaN layer; and

a second gate electrode provided on a gate insulating film provided inside a groove which is provided in the AlₓGa₁₋ₓN layer between the source electrode and the second GaN layer,

the threshold voltage of the second gate electrode being not lower than 0 V,

the source electrode, the first gate electrode and the second gate electrode being electrically connected to each other, or the source electrode and the second gate electrode being electrically connected to each other and a positive voltage being applied to the first gate electrode for the source electrode and the second gate electrode,

an anode electrode being configured by the source electrode, the first gate electrode and the second gate electrode or the source electrode and the second gate electrode and a cathode electrode being configured by the drain electrode.

Here, the electric equipment includes all equipment using electricity and their uses, functions, sizes, and so on are not limited. They are, for example, electronic equipment, mobile bodies, power plants, construction machinery, machine tools, and so on. The electronic equipment may be, for example, robots, computers, game equipment, car equipment, home electric products (air conditioners and so on), industrial products, mobile phones, mobile equipment, IT equipment (servers and so on), power conditioners used in solar power generation systems, power supplying systems, and so on. The mobile bodies are railroad cars, motor vehicles (electric cars and so on), motorcycles, aircrafts, rockets, spaceships, and so on.

In the invention of the electric equipment, the explanation concerning the above invention of the diode comes into effect.

### Effect of the Invention

According to the invention, since the diode is configured by a double gate polarization superjunction GaN-based field effect transistor, it can be used as a high voltage resistance power diode capable of switching high power at high speed. Furthermore, the threshold voltage Vₜₕ of the second gate electrode, which is the on voltage of the diode, can be easily reduced as compared conventional GaN-based Schottky diodes and therefore the energy loss can be reduced. And a high performance electric equipment can be realized by using the excellent diode.

### BRIEF DESCRIPTION OF THE DRAWINGS

FIG. 1 A cross-sectional view showing a PSJ-GaN-based diode according to an embodiment of the invention.

FIG. 2 A schematic view showing a way of connecting electrodes of the PSJ-GaN-based diode according to the embodiment of the invention.

FIG. 3 A schematic view showing another way of connecting electrodes of the PSJ-GaN-based diode according to the embodiment of the invention.

FIG. 4 A cross-sectional view showing the PSJ-GaN-based diode according to the embodiment of the invention using the way of connecting shown in FIG. 2.

FIG. 5 A cross-sectional view showing the PSJ-GaN-based diode according to the embodiment of the invention using the way of connecting shown in FIG. 3.

FIG. 6 A schematic view showing a current-voltage characteristic of the PSJ-GaN-based diode according to the embodiment of the invention.

FIG. 7 A schematic view for explaining the operation principle of the PSJ-GaN-based diode according to the embodiment of the invention.

FIG. 8 A schematic view for explaining the operation principle of the PSJ-GaN-based diode according to the embodiment of the invention.

FIG. 9 A schematic view for explaining the operation principle of the PSJ-GaN-based diode according to the embodiment of the invention.

FIG. 10 A schematic view for explaining the operation principle of the PSJ-GaN-based diode according to the embodiment of the invention.

FIG. 11 A schematic view for explaining the operation principle of the PSJ-GaN-based diode according to the embodiment of the invention.

FIG. 12 A schematic view for explaining the operation principle of the PSJ-GaN-based diode according to the embodiment of the invention.

FIG. 13 A cross-sectional view showing a method for producing the PSJ-GaN-based diode according to the example 1.

FIG. 14 A cross-sectional view showing the method for producing the PSJ-GaN-based diode according to the example 1.

FIG. 15 A cross-sectional view showing the method for producing the PSJ-GaN-based diode according to the example 1.

FIG. 16 A cross-sectional view showing the method for producing the PSJ-GaN-based diode according to the example 1.

FIG. 17 A cross-sectional view showing the method for producing the PSJ-GaN-based diode according to the example 1.

FIG. 18 A cross-sectional view showing the method for producing the PSJ-GaN-based diode according to the example 1.

FIG. 19 A schematic view showing the double gate PSJ-GaN-based FET which configures the PSJ-GaN-based diode produced by the method for producing the PSJ-GaN-based diode according to the example 1.

FIG. 20 A schematic view showing the I_{D}−V_{D} characteristic of the double gate PSJ-GaN-based FET which configures the PSJ-GaN-based diode produced by the method for producing the PSJ-GaN-based diode according to the example 1.

FIG. 21 A schematic view showing the I_{D}−V_{D} characteristic of the double gate PSJ-GaN-based FET which configures the PSJ-GaN-based diode produced by the method for producing the PSJ-GaN-based diode according to the example 1.

FIG. 22 A cross-sectional view showing a method for producing a modification of the PSJ-GaN-based diode according to the example 1.

FIG. 23 A schematic view showing the double gate PSJ-GaN-based FET which configures the PSJ-GaN-based diode produced by the method for producing the modification of the PSJ-GaN-based diode according to the example 1.

FIG. 24 A schematic view showing a current-voltage characteristic of the PSJ-GaN-based diode produced by the method for producing the modification of the PSJ-GaN-based diode according to the example 1.

FIG. 25 A cross-sectional view showing a method for producing the PSJ-GaN-based diode according to the example 2.

FIG. 26 A cross-sectional view showing the method for producing the PSJ-GaN-based diode according to the example 2.

FIG. 27 A cross-sectional view showing the method for producing the PSJ-GaN-based diode according to the example 2.

FIG. 28 A cross-sectional view showing the method for producing the PSJ-GaN-based diode according to the example 2.

FIG. 29 A cross-sectional view showing a method for producing the PSJ-GaN-based diode according to the example 3.

FIG. 30 A cross-sectional view showing the method for producing the PSJ-GaN-based diode according to the example 3.

FIG. 31 A cross-sectional view showing the method for producing the PSJ-GaN-based diode according to the example 3.

FIG. 32 A cross-sectional view showing the method for producing the PSJ-GaN-based diode according to the example 3.

FIG. 33 A cross-sectional view showing the method for producing the PSJ-GaN-based diode according to the example 3.

FIG. 34 A cross-sectional view showing the method for producing the PSJ-GaN-based diode according to the example 3.

FIG. 35 A cross-sectional view showing the method for producing the PSJ-GaN-based diode according to the example 3.

FIG. 36 A cross-sectional view showing the method for producing the PSJ-GaN-based diode according to the example 3.

### MODES FOR CARRYING OUT THE INVENTION

Modes for carrying out the invention (hereinafter referred as embodiments) will now be explained below.

[symbol]

An Embodiment

[symbol]

### [PSJ-GaN-Based Diode]

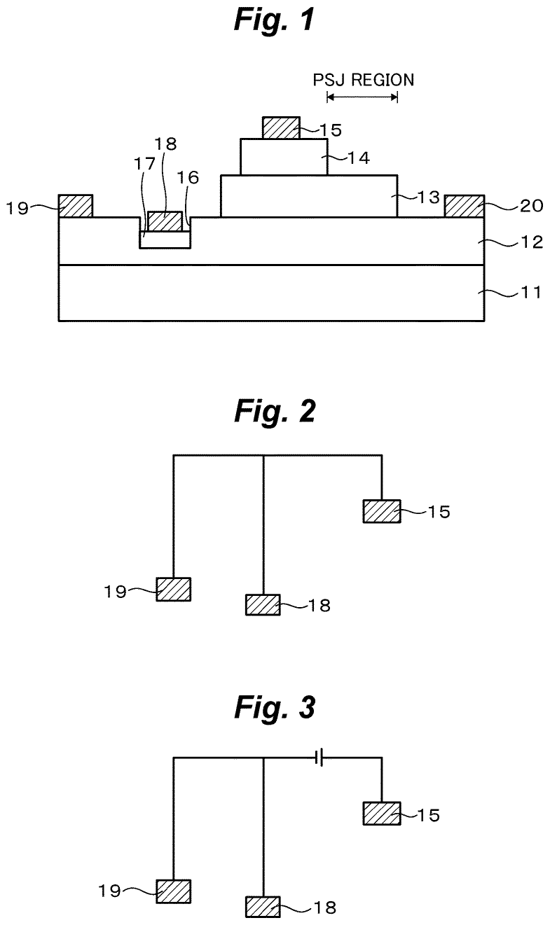

The PSJ-GaN-based diode according to the embodiment is described. FIG. 1 shows the basic structure of the PSJ-GaN-based diode. The PSJ-GaN-based diode is configured by the double gate PSJ-GaN-based FET.

As shown in FIG. 1, in the PSJ-GaN-based diode, a GaN layer 11, an undoped AlₓGa₁₋ₓN layer 12, an undoped GaN layer 13 and a Mg-doped p-type GaN layer 14 are stacked in order. The GaN layer 11 may be undoped or lightly doped with p-type or n-type impurities. The Al composition x of the undoped AlₓGa₁₋ₓN layer 12 is, for example, 0.17≤x≤0.35, but not limited to this. The undoped GaN layer 13 has a fixed island-like planar shape. The p-type GaN layer 14 has an island-like planar shape smaller than the undoped GaN layer 13. Although not illustrated, a p*-type GaN layer which is more heavily doped with Mg than the p-type GaN layer 14 is provided on the surface of the p-type GaN layer 14. Hereinafter, the p⁺-type GaN layer is included in the p-type GaN layer 14. The GaN layer 11, the undoped AlₓGa₁₋ₓN layer 12, the undoped GaN layer 13 and the p-type GaN layer 14 are similar to the PSJ-GaN-based FETs described in the patent literatures 1 and 2, for example.

A first gate electrode 15 is provided on the p-type GaN layer 14 such that the first gate electrode 15 is in ohmic contact with the p-type GaN layer 14. The first gate electrode 15 may be basically any as far as it can be ohmic contact with the p-type GaN layer 14. The first gate electrode 15 is made of for example, Ni film, Ni/Au layered film, and so on. A groove 16 is provided in the undoped AlₓGa₁₋ₓN layer 12 on one side of the undoped GaN layer 13, a gate insulating film 17 made of p-type semiconductor or insulator is buried inside the groove 16, and a second gate electrode 18 is provided on the gate insulating film 17. The second gate electrode 18 is made of a film made of at least one kind of metals selected from a group consisting of Ti, Ni, Au, Pt, Pd, Mo and W. The thickness of the undoped AlₓGa₁₋ₓN layer 12 at the groove 16 is generally not less than 3 nm and not larger than 100 nm, typically not less than 3 nm and not larger than 30 nm. The thickness of the gate insulating film 17 is generally not less than 3 nm and not larger than 100 nm, typically not less than 3 nm and not larger than 30 nm. A source electrode 19 and a drain electrode 20 are provided on the undoped AlₓGa₁₋ₓN layer 12 such that the source electrode 19 and the drain electrode 20 sandwich the undoped GaN layer 13. The source electrode 19 is provided on the opposite side of the undoped GaN layer 13 with respect to the second gate electrode 18.

In the PSJ-GaN-based diode, a part of the undoped GaN layer 13 from the end of the p-type GaN layer 14 on the side of the drain electrode 20 to the end of the undoped GaN layer 13 on the side of the drain electrode 20 and the GaN layer 11 and the undoped AlₓGa₁₋ₓN layer 12 right under it form the PSJ region, whereas the p-type GaN layer 14 and the GaN layer 11, the undoped AlₓGa₁₋ₓN layer 12 and the undoped GaN layer 13 right under it forms the gate electrode contact region.

In the PSJ-GaN-based diode, at a non-operating time (thermal equilibrium), due to piezo polarization and spontaneous polarization, a 2DHG is formed in the undoped GaN layer 13 in the vicinity part of the hetero-interface between the undoped AlₓGa₁₋ₓN layer 12 and the undoped GaN layer 13 and a 2DEG is formed in the GaN layer 11 in the vicinity part of the hetero-interface between the GaN layer 11 and the undoped AlₓGa₁₋ₓN layer 12.

In the PSJ-GaN-based diode, control by the first gate electrode 15 is normally-on type and control by the second gate electrode 18 is normally-off type. The threshold voltage of the second gate electrode 18 is typically not lower than 0 V and not higher than 0.9 V.

There are two ways of connecting the source electrode 19, the first gate electrode 15 and the second gate electrode 18 in the PSJ-GaN-based diode. FIG. 2 shows a connecting way in which the source electrode 19, the first gate electrode 15 and the second gate electrode 18 are electrically connected to each other. FIG. 3 shows another connecting way in which the source electrode 19 and the second gate electrode 18 are electrically connected to each other and a positive certain voltage is applied to the first gate electrode 15 for the source electrode 19 and the second gate electrode 18. According to the connecting way shown in FIG. 3, it is advantageous that it is possible to increase the number of carriers of the 2DEG channel and to increase channel conductivity because the positive certain voltage is applied to the first gate electrode 15.

In the PSJ-GaN-based diode, in case of the connecting way shown in FIG. 2, the source electrode 19, the first gate electrode 15 and the second gate electrode 18 serve as an anode electrode and the drain electrode 20 serves as a cathode electrode, whereas in case of the connecting way shown in FIG. 3, the source electrode 19 and the second gate electrode 18 serve as an anode electrode and the drain electrode 20 serves as a cathode electrode. The PSJ-GaN-based diode can operate as a diode by applying a voltage between the source electrode 19, the first gate electrode 15 and the second gate electrode 18 or the source electrode 19 and the second gate electrode 18 serving as the anode electrode and the drain electrode 20 serving as the cathode electrode.

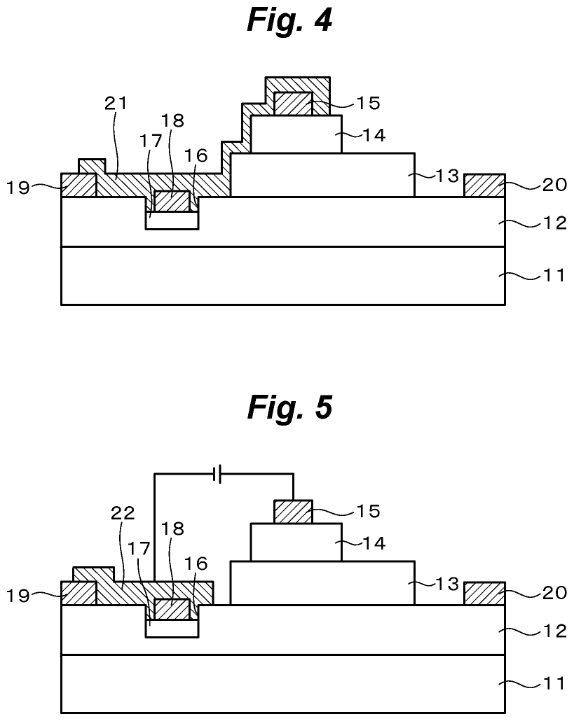

In order to realize connection shown in FIG. 2, as shown in FIG. 4, an electrode 21 made of Au and so on is formed such that it covers the source electrode 19, the first gate electrode 15 and the second gate electrode 18. In order to realize connection shown in FIG. 3, as shown in FIG. 5, an electrode 22 made of Au and so on is formed such that it covers the source electrode 19 and the second gate electrode 18.

### [Operation of the PSJ-GaN-Based Diode]

Described now is operation of the PSJ-GaN-based diode configured by the double gate PSJ-GaN-based FET.

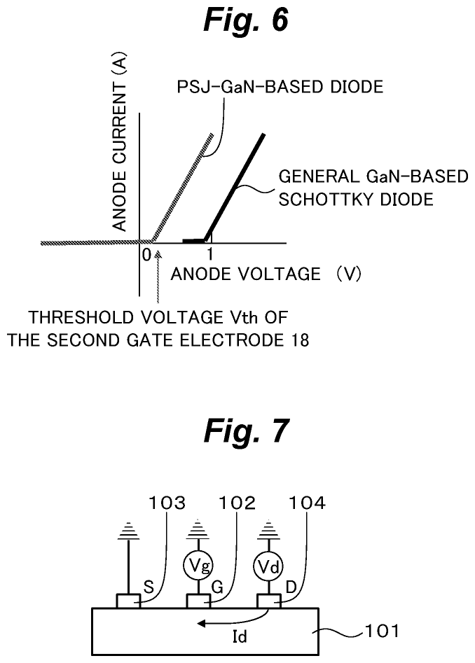

FIG. 6 shows a current-voltage characteristic of the PSJ-GaN-based diode configured by the double gate PSJ-GaN-based FET. As shown in FIG. 6, the rising voltage, i.e., the on voltage is the threshold voltage Vₜₕ of the second gate electrode 18. In FIG. 6, shown also is a current-voltage characteristic of an ordinal GaN-based Schottky diode for comparison. The threshold voltage of the ordinal GaN-based Schottky diode is about 0.9 V. In contrast to this, the threshold voltage Vₜₕ of the PSJ-GaN-based diode can be made to be at least not higher than 0.9 V, typically much lower than that.

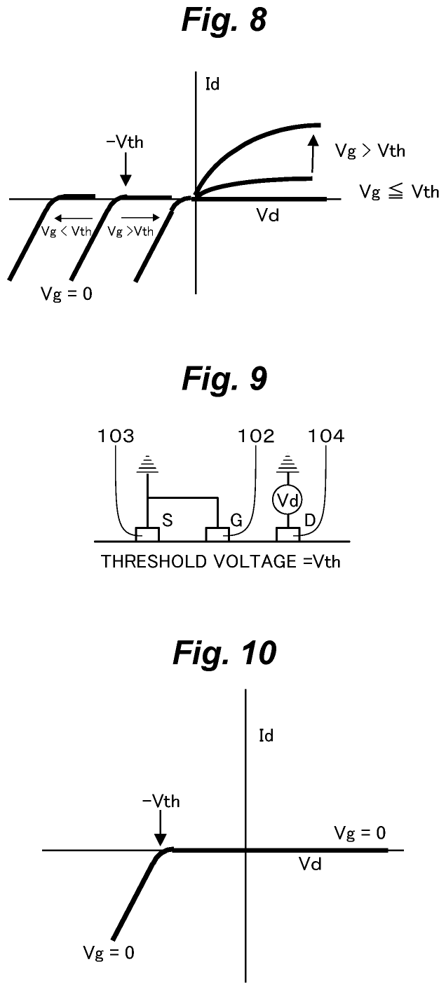

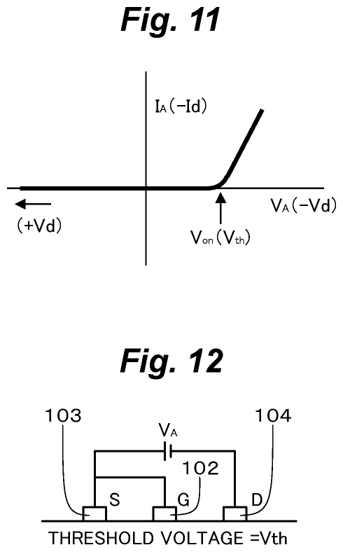

FIG. 7 shows a general three-terminal FET of MESFET type schematically. As shown in FIG. 7, a gate electrode 102, a source electrode 103 and a drain electrode 104 are provided on a channel layer 101. A gate voltage V_{g} is applied to the gate electrode 102 and a drain voltage V_{d} is applied to the drain electrode 104. The source electrode 103 is grounded. The threshold voltage of the three-terminal FET is represented as Vₜₕ. The drain current (I_{d})−drain voltage (V_{d}) characteristic of the three-terminal FET when the drain voltage V_{d} changes from 0 V to the positive side is shown in the first quadrant of FIG. 8 as well known. Here, when V_{g}>Vₜₕ, I_{d} flows. When V_{d} is changed to the negative side, V_{d}<0, and therefore the current flows to the drain electrode 104 side. Then the I_{d}−V_{d} characteristic appears in the third quadrant of FIG. 8. In order to make it possible for the current to flow between the source electrode 103 and the drain electrode 104, V_{d}−V_{g}>Vₜₕ must be satisfied. Furthermore, when V_{g}=0 V, the current flows when V_{d}<−Vₜₕ. Here, V_{g}=0 V corresponds to the case where the voltage of the source electrode 103 and the gate electrode 102 are the same as shown in FIG. 9. When the I_{d}−V_{d} characteristic at V_{g}=0 V is extracted from FIG. 8, it is as shown in FIG. 10. It is seen from FIG. 10 that the I_{d}−V_{d} characteristic is the characteristic of a diode with on voltage=Vₜₕ. In other words, the FET shown in FIG. 9 is equivalent to the diode with the on voltage Vₜₕ shown in FIG. 12 which has the diode characteristic shown in FIG. 11. As a result, the PSJ-GaN-based diode has the characteristic shown in FIG. 6.

### [Method for Producing the PSJ-GaN-Based Diode]

Described is an example of the method for producing the PSJ-GaN-based diode.

Grown on the whole surface of a base substrate (not illustrated) are the undoped or lightly doped GaN layer 11, the undoped AlₓGa₁₋ₓN layer 12, the undoped GaN layer 13 and the p-type GaN layer 14 in order by the conventionally known MOCVD (metal organic chemical vapor deposition) method and so on. As the base substrate, general substrates which have been used so far for growth of GaN layers, for example, a C-plane sapphire substrate, a Si substrate, a SiC substrate, and so on can be used. Then executed are patterning of the undoped GaN layer 13 and the p-type GaN layer 14, formation of the groove 16 in the undoped AlₓGa₁₋ₓN layer 12, filling of the gate insulating film 17 inside the groove 16, formation of the first gate electrode 15, the second gate electrode 18, the source electrode 19 and the drain electrode 20 to produce the PSJ-GaN-based diode shown in FIG. 1. Here, when the groove 16 is formed in the undoped AlₓGa₁₋ₓN layer 12 by etching, an etching stopper made of for example In(Al)GaN and so on is inserted in the depth midway in the thickness direction of the undoped AlₓGa₁₋ₓN layer 12 as necessary. When the connecting way shown in FIG. 2 is used, the electrode 21 which connects the source electrode 19, the first gate electrode 15 and the second gate electrode 18 is formed as shown in FIG. 4. When the connecting way shown in FIG. 3 is used, the electrode 22 which connects the source electrode 19 and the second gate electrode 18 is formed as shown in FIG. 5.

### EXAMPLES

### Example 1

The PSJ-GaN-based diode was produced as follows.

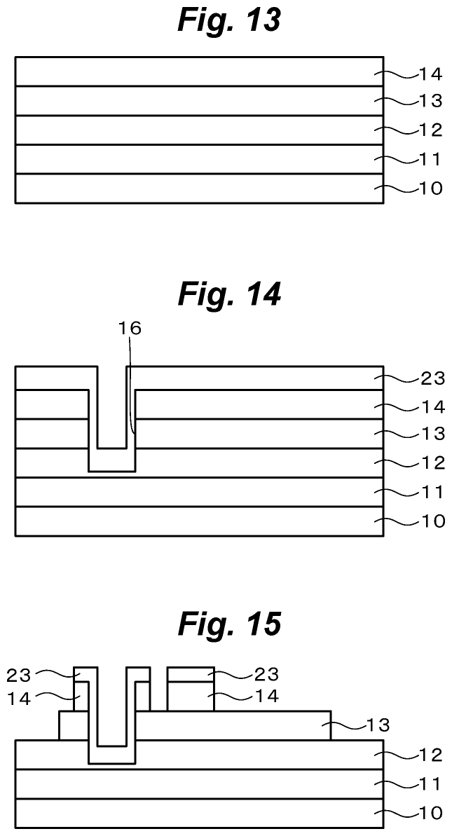

First, as shown in FIG. 13, by the MOCVD method using TMG (trimethyl gallium) as Ga source, TMA (trimethyl aluminium) as Al source, NH₃ (ammonia) as nitrogen source, N₂ gas and H₂ gas as carrier gas, a low temperature growth (530° C.) GaN buffer layer (not illustrated) having a thickness of 30 nm was stacked on the whole surface of the base substrate 10, and then the growth temperature was raised to 1100° C. and the GaN layer 11, the undoped AlₓGa₁₋ₓN layer 12, the undoped GaN layer 13 and the p-type GaN layer 14 were grown in order. As the base substrate 10, a C-plane sapphire substrate was used. The thickness of the GaN layer 11 was 1.0 μm. The thickness of the undoped AlₓGa₁₋ₓN layer 12 was 40 nm and x=0.25. The thickness of the undoped GaN layer 13 was 60 nm. The thickness of the p-type GaN layer 14 was 60 nm and its Mg concentration was 5×10⁸ cm⁻³. The thickness of the p⁺-type GaN layer on the surface of the p-type GaN layer 14 was 3 nm and its Mg concentration was 5×10¹⁹ cm⁻³.

Then, as shown in FIG. 14, the groove 16 was formed in the undoped AlₓGa₁₋ₓN layer 12 by the conventionally known photo lithographic technology and the ICP (inductively coupled plasma) etching technology using Cl-based gasses. More specifically, a resist pattern (not illustrated) having an opening in the part corresponding to the area in which the groove 16 is to be formed was formed on the p-type GaN layer 14. Thereafter, the p-type GaN layer 14, the undoped GaN layer 13 and the undoped AlₓGa₁₋ₓN layer 12 were etched to the depth midway in the thickness direction of the undoped AlₓGa₁₋ₓN layer 12 using the resist pattern as a mask to form the groove 16. Here, the thickness of the undoped AlₓGa₁₋ₓN layer 12 at the groove 16 was set to be about 10 nm. Then a p-type GaN layer 23 having a thickness of about 30 nm was grown on the whole surface by the MOCVD method. The p-type GaN layer 23 was used as the gate insulating film 17.

Then, etched was the part of the GaN layer 11, the undoped AlₓGa₁₋ₓN layer 12, the undoped GaN layer 13 and the p-type GaN layer 14 corresponding to the device isolation region (not illustrated) to the depth midway in the thickness direction of the GaN layer 11. Then, as shown in FIG. 15, the surface of the region in which the second gate electrode 18, the PSJ region and the first gate electrode 15 are to be formed was masked by a resist pattern (not illustrated) having the fixed shape and the p-type GaN layer 23 and the p-type GaN layer 14 were etched in order, to expose the surface of the undoped GaN layer 13. Then, the surface of the region in which the source electrode 19 and the drain electrode 20 are formed was masked by a resist pattern (not illustrated) having the fixed shape and the undoped GaN layer 13 was etched to expose the surface of the undoped AlₓGa₁₋ₓN layer 12.

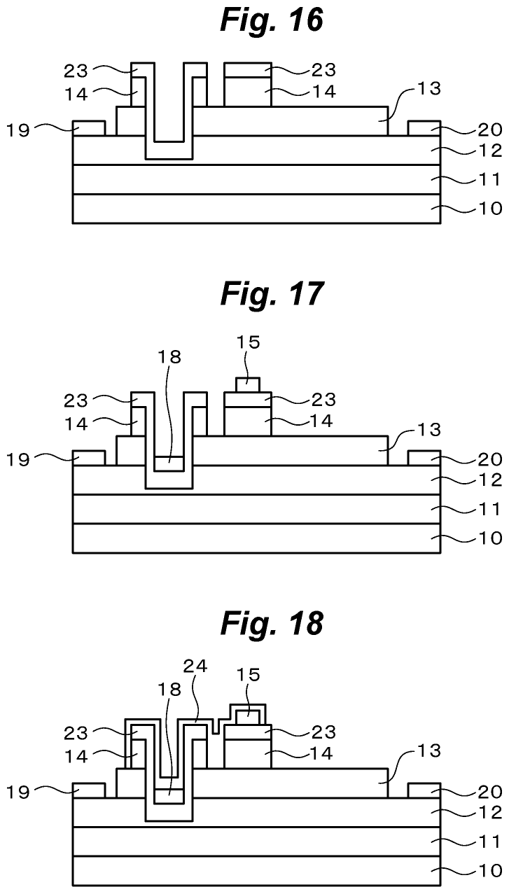

Then, formed was a resist pattern (not illustrated) having openings in parts corresponding to regions in which the source electrode 19 and the drain electrode 20 are to be formed. Thereafter, a Ti film (5 nm), an Al film (50 nm), a Ni film (10 nm) and an Au film (150 nm) were formed in order on the whole surface of the substrate by a vacuum evaporation method. Then, the resist pattern was removed together with the Ti/Al/Ni/Au layered film formed on the resist pattern (lift-off) to form the source electrode 19 and the drain electrode 20 on the undoped AlₓGa₁₋ₓN layer 12 as shown in FIG. 16. Thereafter, rapid thermal annealing (RNA) of 800° C. and 60 seconds was performed in N₂ gas atmosphere to bring the source electrode 19 and the drain electrode 20 into ohmic contact with the undoped AlₓGa₁₋ₓN layer 12.

Then, as shown in FIG. 17, formed was a resist pattern (not illustrated) having openings in parts corresponding to regions in which the first gate electrode 15 and the second gate electrode 18 are to be formed. Thereafter, a Ni film (30 nm) and an Au film (200 nm) were formed in order on the whole surface of the substrate by the vacuum evaporation method. Then, the resist pattern was removed together with the Ni/Au layered film formed on the resist pattern to form the first gate electrode 15 and the second gate electrode 18. Thereafter, thermal annealing of 500° C. and 3 minutes was performed in N₂ gas atmosphere to bring the first gate electrode 15 and the second gate electrode 18 into ohmic contact with the p-type GaN layers 14 and 23, respectively.

Then, as shown in FIG. 18, formed was a resist pattern (not illustrated) having an opening in a part corresponding to the region straddling the first gate electrode 15 and the second gate electrode 18. Thereafter, an Au film (300 nm) was formed on the whole surface of the substrate by the vacuum evaporation method. Then, the resist pattern was removed together with the Au film formed on the resist pattern to form the electrode 24 which connects the second gate electrode 18 and the first gate electrode 15.

In this way, the target PSJ-GaN-based diode was produced.

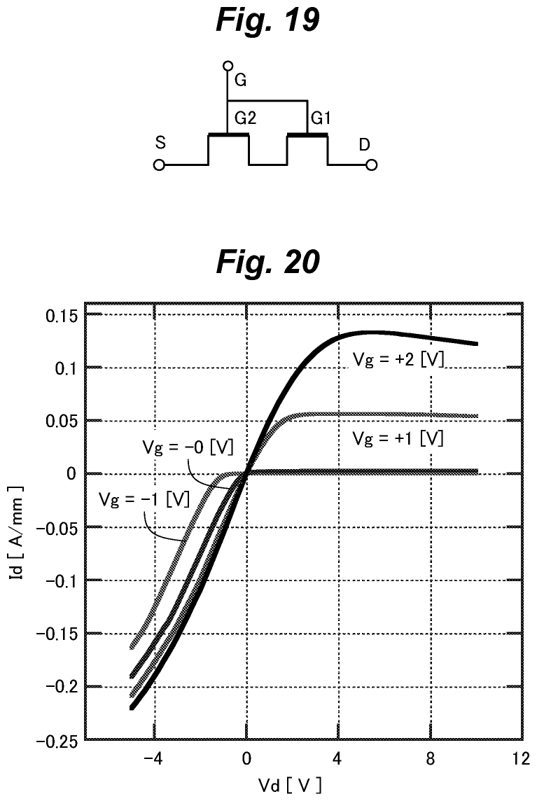

FIG. 19 shows an equivalent circuit of the double gate PSJ-GaN-based FET which configures the PSJ-GaN-based diode produced as described above. In FIG. 19, S, D, G1, G2 show the source electrode 19, the drain electrode 20, the first gate electrode 15 and the second gate electrode 18, respectively and G shows both G1 and G2. FIG. 20 shows the result of measurement of the I_{d}−V_{d} characteristic of the double gate PSJ-GaN-based FET as the three-terminal FET. The measurement was performed for V_{d}=−5 V˜+10 V and V_{g}=−1 V˜+2 V. As understood from FIG. 20, Vₜₕ was about 0 V.

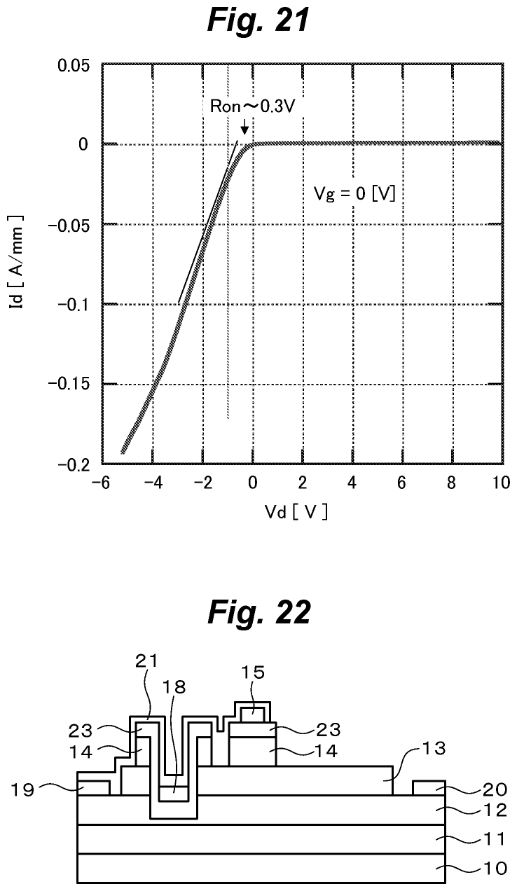

The I_{d}−V_{d} characteristic at V_{g}=0 V was extracted from FIG. 20 and is shown in FIG. 21. Since V_{g}=0 V, the I_{d}−V_{d} characteristic is the characteristic of the two-terminal device shown in FIG. 19 in which G and S are connected. As understood from FIG. 21, the diode characteristic with the rising voltage, i.e., the on voltage Vₒₙ=about 0.3 V was obtained.

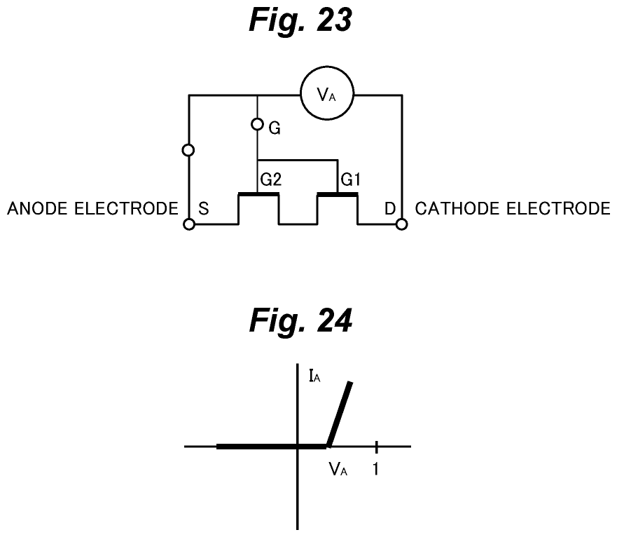

Here, the diode characteristic shown in FIG. 21 was obtained by measuring the I_{d}−V_{d} characteristic of the two-terminal device obtained by connecting the source electrode 19 to the first gate electrode 15 and the second gate electrode 18 outside the device. However, it is possible to connect the source electrode 19 to the first gate electrode 15 and the second gate electrode 18 inside the device by forming the electrode 21 such that the electrode 21 covers the source electrode 19, the first gate electrode 15 and the second gate electrode 18. As shown in FIG. 23, the source electrode 19(S), the first gate electrode 15(G1) and the second gate electrode 18(G2) serve as an anode electrode and the drain electrode 20(D) serves as a cathode electrode. As shown in FIG. 24, when the anode voltage VA is represented in + axis, the polarity of the current is inverted from the one shown in FIG. 21 and normal diode representation is obtained.

### Example 2

The PSJ-GaN-based diode was produced as follows.

First, as the same as the example 1, grown on the whole surface of the base substrate 10 were the GaN layer 11, the undoped AlₓGa₁₋ₓN layer 12, the undoped GaN layer 13 and the p-type GaN layer 14 in order.

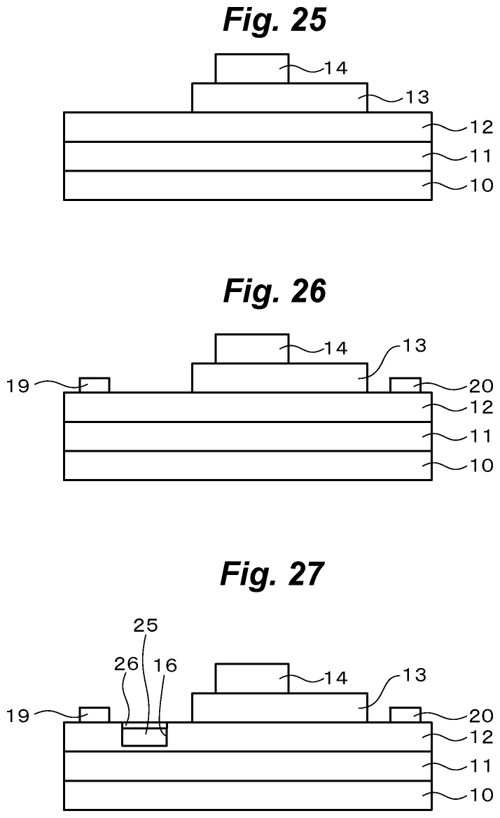

Then, etched was the part of the GaN layer 11, the undoped AlₓGa₁₋ₓN layer 12, the undoped GaN layer 13 and the p-type GaN layer 14 corresponding to the device isolation region (not illustrated) to the depth midway in the thickness direction of the GaN layer 11. Then, as shown in FIG. 25, the undoped GaN layer 13 was exposed by patterning the p-type GaN layer 14 by etching into the fixed shape. Thereafter, the undoped AlₓGa₁₋ₓN layer 12 was exposed by patterning the undoped GaN layer 13 by etching into the fixed shape.

Then, as shown in FIG. 26, as the same as the example 1, the source electrode 19 and the drain electrode 20 were formed on the undoped AlₓGa₁₋ₓN layer 12. Thereafter, RTA of 800° C. and 60 seconds was performed in N₂ gas atmosphere to bring the source electrode 19 and the drain electrode 20 into ohmic contact with the undoped AlₓGa₁₋ₓN layer 12.

Then, as shown in FIG. 27, a resist pattern (not illustrated) having an opening in the part corresponding to the area in which the second gate electrode 18 is to be formed was formed, and then the groove 16 was formed by etching the undoped AlₓGa₁₋ₓN layer 12 using the resist pattern as a mask. Here, the thickness of the undoped AlₓGa₁₋ₓN layer 12 at the groove 16 was set to be about 10 nm. Then leaving the resist pattern as it is, a NiO film (20 nm) and a TiN film (10 nm) were formed in order on the whole surface of the substrate by a sputtering method. Then, the resist pattern was removed together with the NiO/TiN layered film. The total thickness of the NiO film and the TiN film was as the same as the depth of the groove 16. In this way, the NiO film 25 which corresponds to the gate insulating film 17 and the TiN film 26 thereon were formed at the groove 16. Thereafter, annealing was performed in N₂ gas atmosphere to stabilize the NiO film 25. Here, the TiN film 26 serves as a cap layer to prevent oxygen (O) of the NiO film 25 from escaping during thermal annealing.

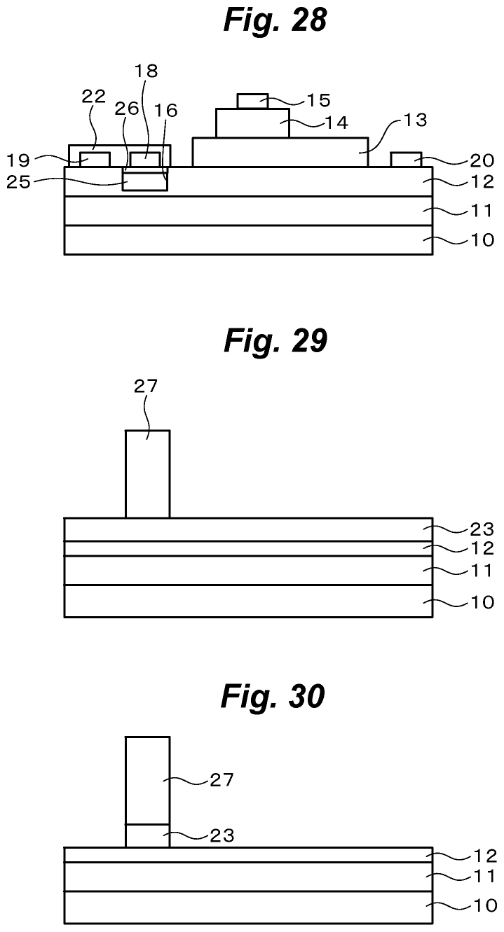

Then, as shown in FIG. 28, formed was a resist pattern (not illustrated) having openings in parts corresponding to regions in which the first gate electrode 15 and the second gate electrode 18 are to be formed. Thereafter, a Ni film (50 nm) and an Au film (150 nm) were formed in order on the whole surface of the substrate by the vacuum evaporation method. Then, the resist pattern was removed together with the Ni/Au layered film formed on the resist pattern to form the first gate electrode 15 and the second gate electrode 18. Thereafter, thermal annealing of 500° C. and 1 minute was performed in N₂ gas atmosphere to bring the first gate electrode 15 and the second gate electrode 18 into ohmic contact with the p-type GaN layer 14 and the NiO film 25, respectively. Thereafter, formed was a resist pattern (not illustrated) having an opening in a part corresponding to the region in which the electrode 22 is to be formed. Then, an Au film (200 nm) was formed on the whole surface of the substrate by the vacuum evaporation method. Then, the resist pattern was removed together with the Au film formed on the resist pattern to form the electrode 22 which covers the source electrode 19 and the second gate electrode 18.

In this way, the target PSJ-GaN-based diode was produced.

### Example 3

The PSJ-GaN-based diode was produced as follows.

First, as shown in FIG. 29, grown on the whole surface of the base substrate 10 were the GaN layer 11, the undoped AlₓGa₁₋ₓN layer 12 and the p-type GaN layer 23 in order by the MOCVD method. The thickness of the GaN layer 11 was 1.0 μm. The thickness of the undoped AlₓGa₁₋ₓN layer 12 was 10 nm and x=0.25. The thickness of the p-type GaN layer 23 was 60 nm and its Mg concentration was 5×10⁸ cm⁻³. The p-type GaN layer 23 finally serves as the gate insulating film 17. Then, an SiO₂ film 27 having the thickness of 0.35 μm was formed on the p-type GaN layer 23 by the vacuum evaporation method. Thereafter, the SiO₂ film 27 was patterned by etching into the fixed shape corresponding to the gate insulating film 17.

Then, as shown in FIG. 30, the p-type GaN layer 23 was patterned by etching using the SiO₂ film 27 patterned as described above as a mask until the undoped AlₓGa₁₋ₓN layer 12 was exposed.

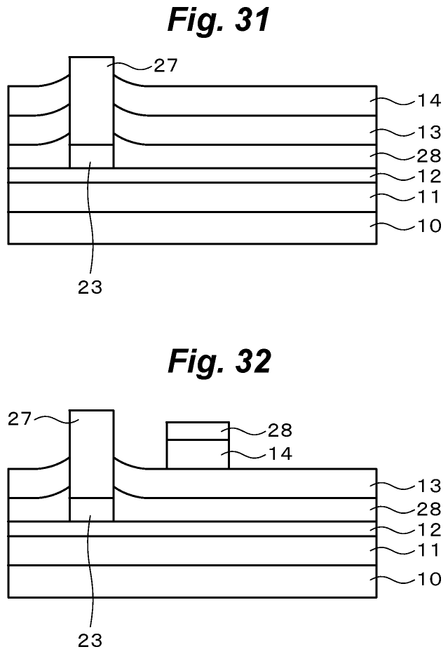

Then, as shown in FIG. 31, grown on the whole surface were an undoped AlₓGa₁₋ₓN layer 28, the undoped GaN layer 13 and the p-type GaN layer 14 in order by the MOCVD method. The thickness of the undoped AlₓGa₁₋ₓN layer 28 was 30 nm and x=0.25. The thickness of the undoped GaN layer 13 was 65 nm. The thickness of the p-type GaN layer 14 was 65 nm and its Mg concentration was 5×10⁸ cm⁻³. The thickness of the surface p⁺-type GaN layer of the p-type GaN layer 14 was 3 nm and its Mg concentration was 5×10¹⁹ cm⁻³. Here, the undoped AlₓGa₁₋ₓN layer 28, the undoped GaN layer 13 and the p-type GaN layer 14 were not grown on the SiO₂ film 27. In this case, the whole of the undoped AlₓGa₁₋ₓN layer 12 and the undoped AlₓGa₁₋ₓN layer 28 thereon correspond to the undoped AlₓGa₁₋ₓN layer 12 shown in FIG. 1.

Then, as shown in FIG. 32, leaving the SiO₂ film 27 as it is, an SiO₂ film 28 was formed on the whole surface and then the SiO₂ film 28 was patterned into a shape corresponding to the p-type GaN layer 14 which is formed finally. Thereafter, the p-type GaN layer 14 was patterned by etching using the SiO₂ film 28 which was patterned as described above as a mask until the undoped GaN layer 13 was exposed.

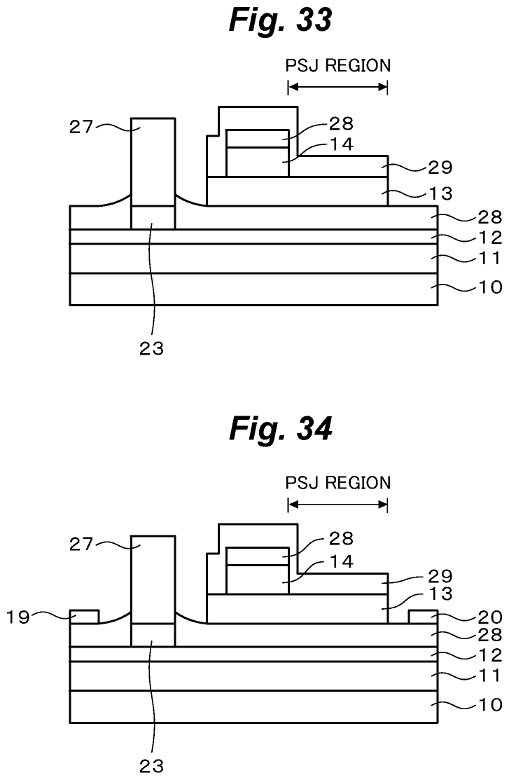

Then, as shown in FIG. 33, leaving the SiO₂ films 27 and 28 as they are, an SiO₂ film 29 having the thickness of 0.2 μm was further formed on the whole surface and then the SiO₂ film 29 was patterned into a shape corresponding to the undoped GaN layer 13 which is formed finally. Thereafter, the undoped GaN layer 13 was patterned by etching using the SiO₂ film 29 which was patterned as described above as a mask until the undoped AlₓGa₁₋ₓN layer 28 was exposed.

Then, as shown in FIG. 34, the source electrode 19 and the drain electrode 20 were formed on the undoped AlₓGa₁₋ₓN layer 28 as the same as the example 1 and then the source electrode 19 and the drain electrode 20 were brought into ohmic contact with the undoped AlₓGa₁₋ₓN layer 28 by performing RTA of 800° C. and 60 seconds in N₂ gas atmosphere.

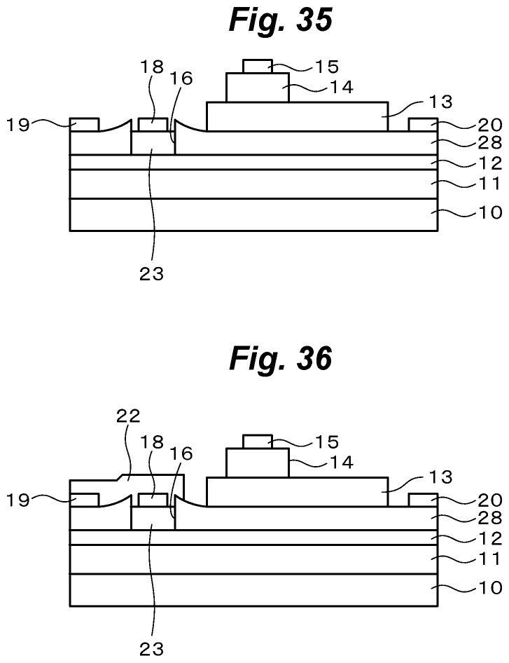

Then, as shown in FIG. 35, the SiO₂ films 27, 28 and 29 were etched off. Thereafter, as the same as the example 2, the first gate electrode 15 and the second gate electrode 18 were formed on the p-type GaN layer 14 and the p-type GaN layer 23, respectively and then brought into ohmic contact with them.

Then, as shown in FIG. 36, formed was a resist pattern (not illustrated) having an opening in a part corresponding to the region straddling the source electrode 19 and the second gate electrode 18. Thereafter, a Ti film (5 nm) and an Au film (200 nm) were formed in order on the whole surface of the substrate by the vacuum evaporation method. Then, the resist pattern was removed together with the Ti/Au layered film formed on the resist pattern to form the electrode 22 which electrically connects the source electrode 19 and the second gate electrode 18.

In this way, the target PSJ-GaN-based diode was produced.

As described above, according to the embodiment, since the PSJ-GaN-based diode is configured by the double gate PSJ-GaN-based FET, it is possible to use the diode as a high voltage resistance power diode which can perform fast switching of high power. Furthermore, since the threshold voltage Vₜₕ of the second gate electrode 18, which is the on voltage of the diode, can be lowered to be not lower than 0 V and not higher than 0.9 V, for example 0.3 V, which is lower than the conventional GaN-based Schottky diode, enabling reduction of energy loss. Since energy loss can be reduced as described above, it is possible to obtain the PSJ-GaN-based diode with low power consumption and low heat generation to realize reduction of size of the PSJ-GaN-based diode. And finally, it is possible to realize a high performance electric equipment by using the excellent PSJ-GaN-based diode.

Heretofore, embodiments of the present invention have been explained specifically. However, the present invention is not limited to these embodiments, but contemplates various changes and modifications based on the technical idea of the present invention.

For example, numerical numbers, structures, shapes, materials, and so on presented in the aforementioned embodiments are only examples, and the different numerical numbers, structures, shapes, materials, and so on may be used as needed.

### EXPLANATION OF REFERENCE NUMERALS

10 Base substrate
11 GaN layer
12 Undoped AlₓGa₁₋ₓN layer
13 Undoped GaN layer
14 p-type GaN layer
15 First gate electrode
16 Groove
17 Gate insulating film
18 Second gate electrode
19 Source electrode
20 Drain electrode

1. A diode configured by a double gate polarization superjunction GaN-based field effect transistor, comprising:
a first GaN layer,
an AlₓGa₁₋ₓN layer (0<x<1) on the first GaN layer,
an undoped second GaN layer having a first island-like shape on the AlₓGa₁₋ₓN layer,
a p-type GaN layer having a second island-like shape on the second GaN layer,
a source electrode and a drain electrode provided on the AlₓGa₁₋ₓN layer such that the source electrode and the drain electrode sandwich the second GaN layer,
a first gate electrode which is electrically connected to the p-type GaN layer; and
a second gate electrode provided on a gate insulating film provided inside a groove which is provided in the AlₓGa₁₋ₓN layer between the source electrode and the second GaN layer,
the threshold voltage of the second gate electrode being not lower than 0 V,
the source electrode, the first gate electrode and the second gate electrode being electrically connected to each other, or the source electrode and the second gate electrode being electrically connected to each other and a positive voltage being applied to the first gate electrode for the source electrode and the second gate electrode,
an anode electrode being configured by the source electrode, the first gate electrode and the second gate electrode or the source electrode and the second gate electrode and a cathode electrode being configured by the drain electrode.

2. The diode according to claim 1, wherein control by the first gate electrode is normally-on type and control by the second gate electrode is normally-off type.

3. The diode according to claim 1, wherein the threshold voltage of the second gate electrode is not lower than 0 V and not higher than 0.9 V.

4. The diode according to claim 1, wherein the source electrode, the first gate electrode and the second gate electrode are electrically connected to each other by providing an electrode such that the electrode covers the source electrode, the first gate electrode and the second gate electrode.

5. The diode according to claim 1, wherein the source electrode and the second gate electrode are electrically connected to each other by providing an electrode such that the electrode covers the source electrode and the second gate electrode.

6. The diode according to claim 1, wherein the thickness of the AlₓGa₁₋ₓN layer at the groove is not smaller than 3 nm and not larger than 100 nm.

7. The diode according to claim 1, wherein the gate insulating film is made of p-type semiconductor or insulator.

8. The diode according to claim 7, wherein the p-type semiconductor is p-type GaN, p-type InGaN or NiOₓ.

9. The diode according to claim 7, wherein the insulator is inorganic oxide, inorganic nitride or inorganic oxynitride.

10. The diode according to claim 7, wherein the insulator is Al₂O₃, SiO₂, AlN, SiNₓ or SiON.

11. A method for producing a diode configured by a double gate polarization superjunction GaN-based field effect transistor, comprising:
a first GaN layer,
an AlₓGa₁₋ₓN layer (0<x<1) on the first GaN layer,
an undoped second GaN layer having a first island-like shape on the AlₓGa₁₋ₓN layer,
a p-type GaN layer having a second island-like shape on the second GaN layer,
a source electrode and a drain electrode provided on the AlₓGa₁₋ₓN layer such that the source electrode and the drain electrode sandwich the second GaN layer,
a first gate electrode which is electrically connected to the p-type GaN layer; and
a second gate electrode provided on a gate insulating film provided inside a groove which is provided in the AlₓGa₁₋ₓN layer between the source electrode and the second GaN layer,
the threshold voltage of the second gate electrode being not lower than 0 V,
the source electrode, the first gate electrode and the second gate electrode being electrically connected to each other, or the source electrode and the second gate electrode being electrically connected to each other and a positive voltage being applied to the first gate electrode for the source electrode and the second gate electrode,
an anode electrode being configured by the source electrode, the first gate electrode and the second gate electrode or the source electrode and the second gate electrode and a cathode electrode being configured by the drain electrode, comprising steps of:
growing the first GaN layer, the AlₓGa₁₋ₓN layer, the second GaN layer and the p-type GaN layer on the whole surface of a base substrate in order,
forming the groove by etching a part of the p-type GaN layer, the second GaN layer and the AlₓGa₁₋ₓN layer corresponding to an area for forming the groove to the depth in the middle of the AlₓGa₁₋ₓN layer,
growing a p-type GaN layer for forming the gate insulating film on the p-type GaN layer such that the p-type GaN layer for forming the gate insulating film fills the groove,
forming the second island-like shape and the gate insulating film by patterning the p-type GaN layer for forming the gate insulating film and the p-type GaN layer by etching,
forming the source electrode and the drain electrode on the AlₓGa₁₋ₓN layer,
forming the first gate electrode and the second gate electrode on the p-type GaN layer for forming the gate insulating film formed as the second island-like shape and the gate insulating film, respectively; and
forming an electrode which covers the source electrode, the first gate electrode and the second gate electrode or an electrode which covers the source electrode and the second gate electrode.

12. A method for producing a diode configured by a double gate polarization superjunction GaN-based field effect transistor, comprising:
a first GaN layer,
an AlₓGa₁₋ₓN layer (0<x<1) on the first GaN layer,
an undoped second GaN layer having a first island-like shape on the AlₓGa₁₋ₓN layer,
a p-type GaN layer having a second island-like shape on the second GaN layer,
a source electrode and a drain electrode provided on the AlₓGa₁₋ₓN layer such that the source electrode and the drain electrode sandwich the second GaN layer,
a first gate electrode which is electrically connected to the p-type GaN layer; and
a second gate electrode provided on a gate insulating film provided inside a groove which is provided in the AlₓGa₁₋ₓN layer between the source electrode and the second GaN layer,
the threshold voltage of the second gate electrode being not lower than 0 V,
the source electrode, the first gate electrode and the second gate electrode being electrically connected to each other, or the source electrode and the second gate electrode being electrically connected to each other and a positive voltage being applied to the first gate electrode for the source electrode and the second gate electrode,
an anode electrode being configured by the source electrode, the first gate electrode and the second gate electrode or the source electrode and the second gate electrode and a cathode electrode being configured by the drain electrode, comprising steps of:
growing the first GaN layer, the AlₓGa₁₋ₓN layer, the second GaN layer and the p-type GaN layer on the whole surface of a base substrate in order,
patterning the p-type GaN layer and the second GaN layer by etching as the second island-like shape and the first island-like shape, respectively,
forming the source electrode and the drain electrode on the AlₓGa₁₋ₓN layer,
forming the groove by etching a part of the AlₓGa₁₋ₓN layer corresponding to an area for forming the groove to the depth in the middle of the AlₓGa₁₋ₓN layer,
forming the gate insulating film inside the groove,
forming the first gate electrode and the second gate electrode on the p-type GaN layer and the gate insulating film, respectively; and
forming an electrode which covers the source electrode, the first gate electrode and the second gate electrode or an electrode which covers the source electrode and the second gate electrode.

13. A method for producing a diode configured by a double gate polarization superjunction GaN-based field effect transistor, comprising:
a first GaN layer,
an AlₓGa₁₋ₓN layer (0<x<1) on the first GaN layer,
an undoped second GaN layer having a first island-like shape on the AlₓGa₁₋ₓN layer,
a p-type GaN layer having a second island-like shape on the second GaN layer,
a source electrode and a drain electrode provided on the AlₓGa₁₋ₓN layer such that the source electrode and the drain electrode sandwich the second GaN layer,
a first gate electrode which is electrically connected to the p-type GaN layer; and
a second gate electrode provided on a gate insulating film provided inside a groove which is provided in the AlₓGa₁₋ₓN layer between the source electrode and the second GaN layer,
the threshold voltage of the second gate electrode being not lower than 0 V,
the source electrode, the first gate electrode and the second gate electrode being electrically connected to each other, or the source electrode and the second gate electrode being electrically connected to each other and a positive voltage being applied to the first gate electrode for the source electrode and the second gate electrode,
an anode electrode being configured by the source electrode, the first gate electrode and the second gate electrode or the source electrode and the second gate electrode and a cathode electrode being configured by the drain electrode, comprising steps of:
growing the first GaN layer, a first AlₓGa₁₋ₓN layer and a p-type GaN layer for forming the gate insulating film on the whole surface of a base substrate in order,
forming a first mask made of inorganic insulator having the same shape as the groove on the p-type GaN layer for forming the gate insulating film,
forming the gate insulating film by patterning the p-type GaN layer for forming the gate insulating film by etching using the first mask as an etching mask,
growing a second AlₓGa₁₋ₓN layer, the second GaN layer and the p-type GaN layer on the first AlₓGa₁₋ₓN layer in order by using the first mask as a growth mask,
forming a second mask made of inorganic insulator having the same shape as the second island-like shape on the p-type GaN layer,
patterning the p-type GaN layer by etching using the second mask as an etching mask,
forming a third mask made of inorganic insulator having the same shape as the first island-like shape such that the third mask covers the second mask,
patterning the second p-type GaN layer by etching using the third mask as an etching mask,
forming the source electrode and the drain electrode on the second AlₓGa₁₋ₓN layer,
forming the first gate electrode and the second gate electrode on the p-type GaN layer and the gate insulating film, respectively; and
forming an electrode which covers the source electrode, the first gate electrode and the second gate electrode or an electrode which covers the source electrode and the second gate electrode.

14. An electric equipment comprising at least one diode,
the diode being configured by a double gate polarization superjunction GaN-based field effect transistor, comprising:
a first GaN layer,
an AlₓGa₁₋ₓN layer (0<x<1) on the first GaN layer,
an undoped second GaN layer having a first island-like shape on the AlₓGa₁₋ₓN layer,
a p-type GaN layer having a second island-like shape on the second GaN layer,
a source electrode and a drain electrode provided on the AlₓGa₁₋ₓN layer such that the source electrode and the drain electrode sandwich the second GaN layer,
a first gate electrode which is electrically connected to the p-type GaN layer; and
a second gate electrode provided on a gate insulating film provided inside a groove which is provided in the AlₓGa₁₋ₓN layer between the source electrode and the second GaN layer,
the threshold voltage of the second gate electrode being not lower than 0 V,
the source electrode, the first gate electrode and the second gate electrode being electrically connected to each other, or the source electrode and the second gate electrode being electrically connected to each other and a positive voltage being applied to the first gate electrode for the source electrode and the second gate electrode,
an anode electrode being configured by the source electrode, the first gate electrode and the second gate electrode or the source electrode and the second gate electrode and a cathode electrode being configured by the drain electrode.
